(19) United States
(12) Patent Application Publication
(10) Pub. No.: US 2023/0146234 A1
(43) Pub. Date: May 11, 2023

(54) Fabrication Method of MEMS Transducer Element

(71) Applicant: TE Connectivity Solutions GmbH, Schaffhausen (CH)

(72) Inventors: Jean-Francois Le Neal, Schaffhausen (CH); Kaspar Jenni, Muhlenstrasse (CH)

(73) Assignee: TE Connectivity Solutions GmbH, Schaffhausen (CH)

(21) Appl. No.: 17/980,055

(22) Filed: Nov. 3, 2022

(30) Foreign Application Priority Data
Nov. 5, 2021 (EP) 21206693.0

(51) Int. Cl. B81B 7/00; B81C 1/00; G01L 9/00

(52) U.S. Cl. CPC B81B 7/0058; B81B 7/0041; B81C 1/00293; B81C 1/00333; G01L 9/0051; G01L 9/0072; B81B 2201/0264; B81B 2203/0127; B81B 2203/04; B81B 2207/096; B81C 2203/019

(57) ABSTRACT

A method of fabricating a plurality of individual microelectromechanical transducer elements includes forming a plurality of microelectromechanical transducer elements on a wafer. Each microelectromechanical transducer element has a sensitive region with a membrane and a sensing element monitoring at least one measurand and generating an electrical signal correlated with the at least one measurand, and an electrical contact outputting the electrical signal. The method includes providing, for each microelectromechanical transducer element, a sealing structure around a sensitive region and an electrical connection connected to the electrical contact. The sealing structure and the electrical connection are made out of a reflow solder material. The method includes dicing the wafer to form individual microelectromechanical transducer elements.

### CROSS-REFERENCE TO RELATED APPLICATION

This application claims the benefit of the filing date under 35 U.S.C. § 119(a)-(d) of European Patent Application No. 21206693.0, filed on Nov. 5, 2021.

### FIELD OF THE INVENTION

The present invention relates to a method of fabricating a plurality of microelectromechanical (MEMS) transducer element and a microelectromechanical (MEMS) sensor arrangement as well as to a micromechanical (MEMs) transducer element for monitoring at least one measurand and for generating an electrical output signal correlated with the at least one measurand.

### BACKGROUND

MEMs sensor arrangements are known in the art and comprise a transducer element for monitoring at least one measurand and generating an electrical output signal correlated with the at least one measurand. The medium, which is to be monitored, must gain access to defined sensitive elements of the sensor arrangement while it must be ensured that a potentially aggressive and/or humid environment does not damage and/or impair the remaining parts. This is in particular true for electronic components of the sensor arrangement.

Furthermore, component suppliers provide sensor components in a not yet fully assembled state to the original equipment manufacturers (OEM). Thus, providing a sealing that protects the electronic components must be facilitated. This sealing should allow for an automated assembly procedure performed outside the premises of the component supplier.

Such a MEMS sensor arrangement is known from EP 3 456 682 A1. A side cut view of the sensor arrangement 100 is shown in FIG. 1. The sensor arrangement 100 comprises a ceramic sensor 102 with a transducer element 104 mounted onto a substrate 106. A channel 108 is provided in the substrate 106. The medium to be monitored enters through the channel 108 to impinge onto the transducer element 104. The ceramic sensor 102 further comprises a transducer substrate 110 and side wall electrodes 112. Using contact pads 114, the electrodes 112 are connected to electrical leads 116 that are provided on the surface of the substrate 106 to electrically connect the transducer element 104 to further electrical components 118 of the sensor arrangement 100.

A solder seal 120 is provided between the transducer element 104 and the substrate 106 around the media channel 108 to seal and protect the electrical components 118, the electrical leads 116, the contact pads 114 and the electrodes 112 from the media channel 108. In addition, a protective cover 122 made from plastics, ceramic, glass or from an electrically conductive material, is provided to protect the transducer element 102.

Typically, the ceramic sensor 102 is fabricated by the sensor manufacturer which also provides a first level packaging and sealing of the sensor and it is then delivered to an OEM who takes care of the electrical connections and pressure port sealing. The sensor sealing and its connectivity to the electrical components 118 is still challenging, as it is time consuming and quality control still tedious.

### SUMMARY

A method of fabricating a plurality of individual microelectromechanical transducer elements includes forming a plurality of microelectromechanical transducer elements on a wafer. Each microelectromechanical transducer element has a sensitive region with a membrane and a sensing element monitoring at least one measurand and generating an electrical signal correlated with the at least one measurand, and an electrical contact outputting the electrical signal. The method includes providing, for each microelectromechanical transducer element, a sealing structure around a sensitive region and an electrical connection connected to the electrical contact. The sealing structure and the electrical connection are made out of a reflow solder material. The method includes dicing the wafer to form individual microelectromechanical transducer elements.

### BRIEF DESCRIPTION OF THE DRAWINGS

The invention may be understood by reference to the following description taken in conjunction with the accompanying figures, in which reference numerals identify features of the invention.

FIG. 1 illustrates a schematic side cut view of a microelectromechanical (MEMS) sensor system according to the state of the art;

FIG. 2a illustrates a schematic view of a fabrication method of a microelectromechanical transducer element according to a first embodiment of the invention;

FIG. 2b illustrates a side view of a microelectromechanical transducer element according to a variant of the first embodiment of the invention;

FIG. 2c illustrates a top view of the microelectromechanical transducer element obtained with the fabrication method according to the first embodiment of the invention;

FIG. 2d illustrates a schematic view of a fabrication method of a microelectromechanical sensor arrangement according to a variant of the first embodiment of the invention;

FIG. 2e illustrates a schematic view of a fabrication method of a microelectromechanical sensor arrangement according to a second variant of the first embodiment of the invention;

FIG. 2f illustrates a schematic view of a fabrication method of a microelectromechanical sensor arrangement according to a third variant of the first embodiment of the invention;

FIG. 3a illustrates a schematic view of a fabrication method of a microelectromechanical transducer element according to a second embodiment of the invention;

FIG. 3b illustrates a schematic view of a microelectromechanical sensor arrangement according to a variant of the second embodiment of the invention;

FIG. 3c illustrates a schematic view of a microelectromechanical sensor arrangement according to a second variant of the second embodiment of the invention;

FIG. 4a illustrates a schematic view of a fabrication method of a microelectromechanical transducer element according to a third embodiment of the invention;

FIG. 4b illustrates a schematic view of a fabrication method of a microelectromechanical sensor arrangement according to a variant of the third embodiment of the invention;

FIG. 5a illustrates a schematic view of a fabrication method of microelectromechanical transducer element fabricated according to a fourth embodiment of the invention;

FIG. 5b illustrates a schematic view of a microelectromechanical sensor arrangement according to a variant of the fourth embodiment of the invention;

FIG. 6a illustrates a schematic view of a fabrication method of microelectromechanical transducer element fabricated according to a fifth embodiment of the invention;

FIG. 6b illustrates a schematic view of a microelectromechanical sensor arrangement according to a variant of the fifth embodiment of the invention;

FIG. 7a illustrates a schematic view of a transducer element fabricated according to a sixth embodiment of the invention;

FIG. 7b illustrates a schematic view of a microelectromechanical sensor arrangement according to a variant of the sixth embodiment of the invention;

FIG. 8a illustrates a schematic view of a transducer element fabricated according to a seventh embodiment of the invention;

FIG. 8b illustrates a schematic view of a microelectromechanical sensor arrangement fabricated according to a variant of the seventh embodiment of the invention;

FIG. 8c illustrates a schematic view of a microelectromechanical sensor arrangement fabricated according to a second variant of the seventh embodiment of the invention;

FIG. 8d illustrates a schematic view of a microelectromechanical sensor arrangement fabricated according to a third variant of the seventh embodiment of the invention; and

FIG. 9 illustrates a schematic view of a microelectromechanical sensor system according to an eighth embodiment of the invention.

### DETAILED DESCRIPTION OF THE EMBODIMENT(S)

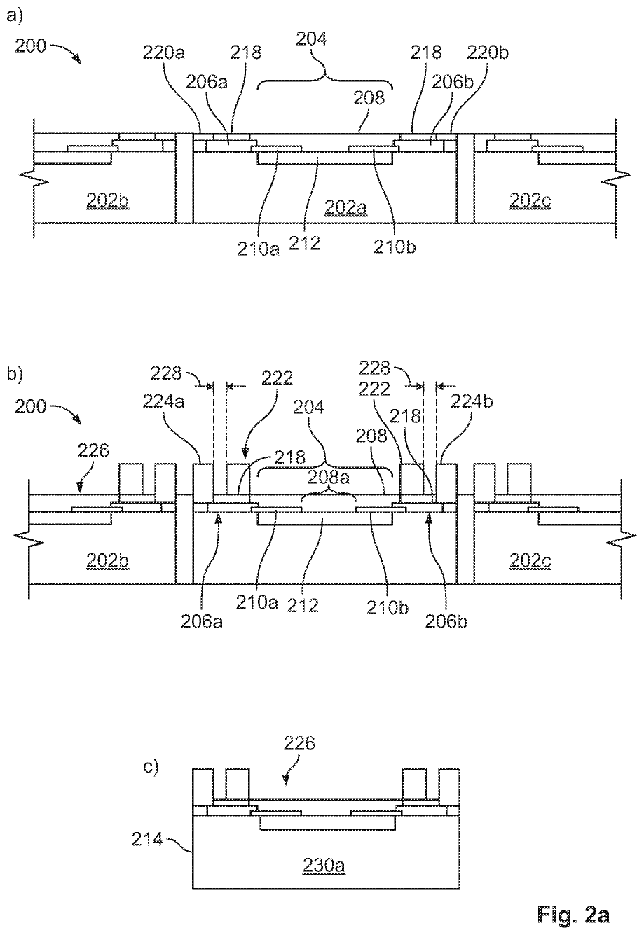

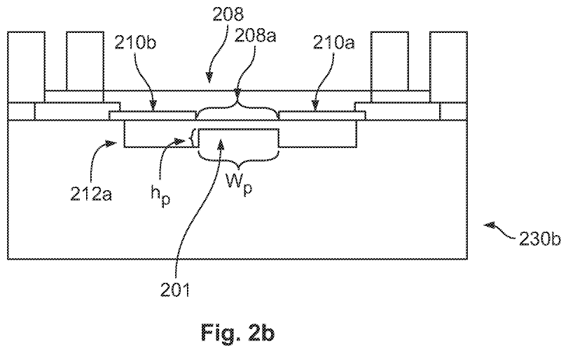

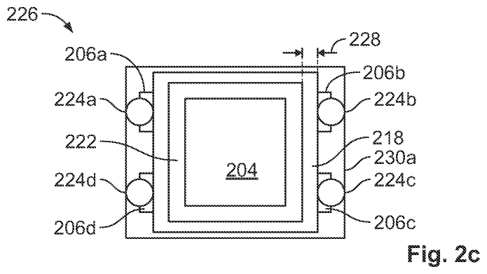

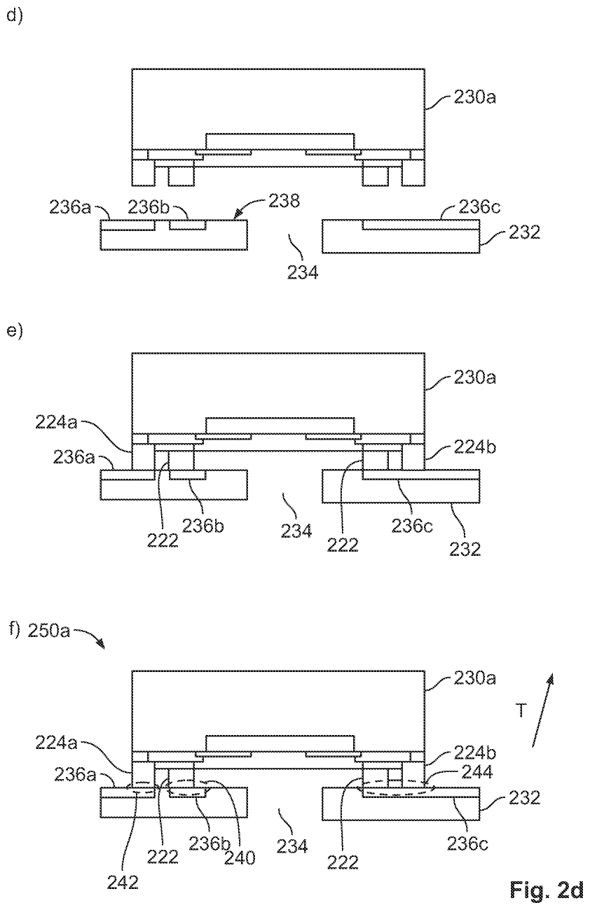

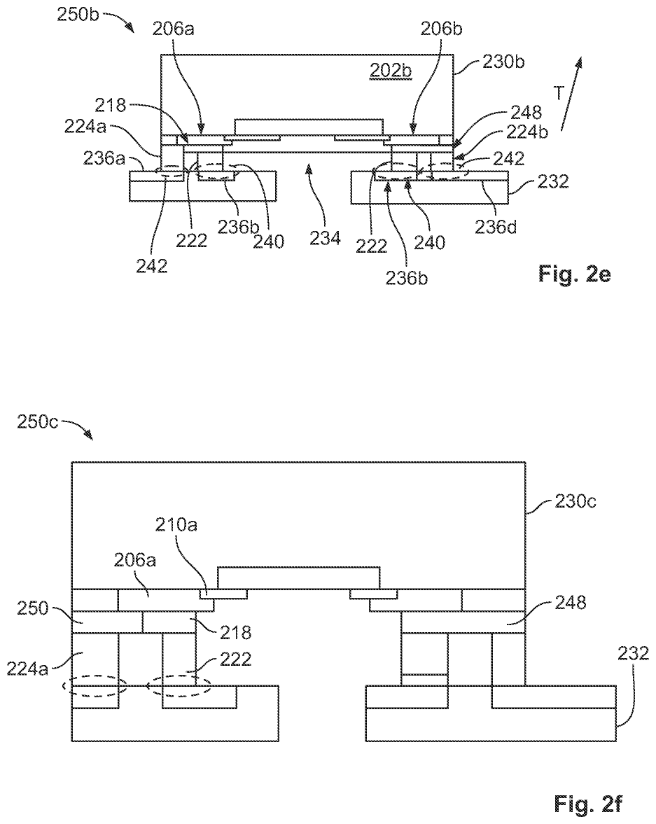

FIG. 2a shows a schematic diagram of a method of fabrication of a plurality of individual microelectromechanical transducer elements according to a first embodiment of the invention. The method comprises a step a) of realizing a plurality of individual transducer elements 202a, 202b, 202c on a wafer 200, e.g. a silicon wafer, using a microelectromechanical device fabrication process as known in the art. The individual microelectromechanical transducer elements 202a, 202b, 202c of the plurality of microelectromechanical transducer elements all have the same structural features. Here, only transducer element 202a will be described in detail, transducer elements 202b, 202c like all other transducer elements on the wafer 200 are realized in the same way.

The transducer element 202a comprises a sensitive region 204 for monitoring at least one measurand and generating an electrical signal correlated with the at least one measurand, and one or more electrical contacts 206a, 206b for outputting the electrical signal. The sensitive region 204 comprises a membrane 208, also called diaphragm, carrying a plurality of sensing elements 210a, 210b electrically connected to the one or more electrical contacts 206a, 206b. The membrane 208 of the sensitive region 204 is provided above a cavity 212 in the wafer 200. In the embodiment illustrated, the sensing elements 210a, 210b are facing the inner cavity 212. In an alternative, they could be provided on the other side of the membrane 208 thus facing away from the cavity 212. The sensing elements 210a, 210b can be strain gauges or capacitive structures.

In the embodiment shown in FIG. 2a, the sensing elements 210a, 210b are provided between the membrane 208 and the inner cavity 212. In an alternative, the sensing elements 210a, 210b can also be provided above the membrane 208, on the surface 226 of the wafer.

The electrical contacts 206a, 206b are electrically connected with the sensing elements 210a, 210b respectively. An insulating or non-conductive layer 218 is deposited at least partially over the electrical contacts 206a, 206b respectively. A portion 220a, 220b of the electrical contacts 206a, 206b remains uncovered.

According to the invention, the method then comprises a step b) shown in FIG. 2a of providing, for each microelectromechanical transducer element 202a, 202b, 202c, a sealing structure 222 around its sensitive region 204 and electrical connections 224a, 224b electrically connected respectively to the electrical contacts 206a, 206b.

According to the invention, the sealing structure 222 and the electrical connections 224a and 224b are made out of the same material, in particular a solder material, more in particular a reflow solder material. Thus, the sealing structure 222 and the electrical connections 224a, 224b can be realized during the same process step. To realize the sealing structure 222 and the electrical connections 224a, 224b, a layer of a solder material is deposited on the wafer 200 and then patterned e.g. using screen printing or photolithography techniques known in the art. Alternatively, bumping or electrolytic metal deposition techniques can be used as well. As a result, the process is less complex and can be realized faster since only one step is required for providing both the sealing structure 222 and the electrical connections 224a, 224b for the plurality of transducer elements 202a, 202b, 202c on the wafer 200.

In this embodiment, the sealing structure 222 and the electrical connections 224a, 224b are provided on the same surface side 226 of the wafer 200, namely the side with the membrane 208 of the transducer elements 202a, 202b, 202c. The sealing structure 222 and the electrical connection structure 224a, 224b are separated by a gap 228 to be electrically isolated from each other. According to a variant of the invention, the step b) can comprise providing the sealing structure 222 and the electrical connection structure 224a, 224b over opposite sides of the wafer 200. In this variant, the electrical contacts 206a, 206b can be arranged further away from the potentially aggressive and/or humid environment provided by the measurand entering the device.

The sealing structure 222 is provided at least partially over the insulating layer 218 to be electrically isolated from the electrical contacts 206a, 206b of the transducer element 202a. In contrast thereto, the electrical connections 224a, 224b are arranged at least partially on the free portion 220a, 220b of the electrical contacts 206a, 206b to realize an electrical contact with the electrical contacts 206a, 206b. The sealing structure 222 is realized such that it surrounds the active region 204 of the membrane 208.

Then, according to step c) of the inventive method shown in FIG. 2a, the wafer 200 is diced to form individual microelectromechanical transducer elements. Here only the individual transducer element 230a is illustrated. In the following a wafer 200 that has been diced, will be called a transducer substrate 214.

FIG. 2b illustrates a transducer element 230b according to a variant. The only difference with respect to the transducer element 230a of FIG. 2a is a different shape of the cavity 212a. In this variant, a protrusion 201 remains after realizing the cavity 212a in the wafer 200. The protrusion extends into the cavity 212a towards the membrane 208. The protrusion 201 can have varying heights hp and widths wp. Typically wp is less than the distance 208a between the sensing elements 210a, 210b. The protrusion 201 allows limiting the extent of the flexure of the membrane 208.

FIG. 2c is a schematic view onto an active surface side 226 of the transducer element 230a. As illustrated, the sealing structure 222 surrounds the sensitive region 204 of the transducer element 230a. The sealing structure 222 in this embodiment has a square-shape. However, other forms, like a ring shape, could be used as long as the sealing structure 222 surrounds the sensitive region 204. The electrical connections 224a, 224b, 224c 224d are positioned on the electrical contacts 206a, 206b, 206c, 206d spaced apart by a gap 228 from the sealing structure 222 via the insulating layer 218.

In FIG. 2c, four electrical connections 224a, 224b, 224c and 224d on four electrical contacts 206a, 206b, 206c, 206d are illustrated. However, more or less connection structures and electrical contacts of different shape and size may be used depending on the requirements and the number of sensing elements used.

According to the invention, the individual microelectromechanical transducer element 230a comprises a sealing structure 222 and electrical connections 224a, 224b, 224c and 224d on the active surface side 226 made of the same material and realized already during the MEMS level process steps at the OEM prior to dicing and not on packaging level at the customer site. This simplifies the integration of the transducer element 230a at the customer site.

According to a first variant of the embodiment according the invention illustrated in FIG. 2d, the manufacturing process continues after step c) with a step d) of providing a transducer element 230a and a substrate 232, e.g. at a customer site. The substrate 232 can be chip carrier, in particular a ceramic chip carrier, a PCB, a flexible circuit board, a leadframe or the like.

The substrate 232 comprises at least one media channel 234 that extends through the substrate 232. The substrate 232 comprises further contact pads 236a, 236b, 236c provided on a surface 238 of the substrate 232. The contact pads 236a, 236b, 236c are made of a conductive material, in particular metal.

In the subsequent step e), the transducer element 230a is positioned on the substrate 232. Here, the electrical connection 224a is aligned with the contact pad 236a and the sealing structure 222 is aligned with the contact pad 236b on the one side of the channel 234 of the substrate 232. On the other side of the channel 234, the sealing structure 222 and the electrical connection 224b are aligned with the contact pad 236c.

Subsequently, a soldering step is realized, illustrated by step f) in FIG. 2d, to thereby seal the media channel 234 from the electrical connections 224a and 224b with the sealing structure 222. At the same time, the transducer element 230a is electrically connected to the substrate 232 via the electrical connections 224a and 224b.

The soldering in step f) may be performed by a reflow soldering technique during which the substrate 232 and the transducer element 230a are heated beyond the fusion point of the solder material used for the sealing structure 222 and the electrical connection structures 224a, 224b. After cooling down, reliable solder connections 240, 242, 244 are established between the substrate 232 and the transducer element 230a, in particular between the contact pad 236a, 236b, 236c of the substrate 232 and the sealing structure 222 and the electrical connection structures 224a, 224b of the transducer elements 230a.

After step f) a MEMs sensor arrangement 250a is obtained that realizes reliable electrical contacts and a reliable protection of the parts of the sensor that are outside the media channel 234.

As shown in step f) of FIG. 2d, the solder connection 240 for sealing between the contact pads 236b and the sealing structure 222 is separated from the solder electrical connection 242 between the contact pad 236a and the electrical connection structure 224a. To the contrary, the solder connection 244 electrically connects the sealing structure 222 and the electrical connection structure 224a via the contact pad 236c. According to an alternative, the sealing structure 222 may be electrically isolated from all sensing elements 210a, 210b, but connected to ground using an additional contact pad on the substrate 232. The formed solder connections 240, 242, 244 form the electrical connections as well as provide a secure sealing against the ingress of humidity and/or aggressive chemicals coming from the media channel 234 into the interface between the transducer element 230a and the substrate 232.

The method provides a plurality of transducer elements 302a on wafer level with a channel 234 for a measurand. With such a transducer further integrated pressure sensors can be realized and/or differential pressure sensors having media channels on both sides of the measuring membrane 208 can be realized.

A second variant of the invention is shown in FIG. 2e illustrating a MEMs sensor arrangement 250b comprising a transducer element 230b connected to a substrate 232. The only difference between this variant and the transducer element 230a and MEMs sensor arrangement 250a, illustrated in FIG. 2d is a different electrical connection between the sealing structure 222 and the electrical connection 224b. All other features remain the same and reference made is to the description above.

Instead of realizing the electrical connection between the sealing structure 222 and the electrical connection 224b on the substrate 232 side using contact pad 236c as shown in FIG. 2d, the electrical connection is realized on the transducer element 202b side using an electrically conductive layer 248.

The electrically conductive layer 248 also electrically connects the electrical contact 206b with the electrical connection 224b. The insulating layer 218 remains present between the electrical contact 206a and the sealing structure 222.

The solder connection 240 with the substrate 232 is then realized between the sealing structure 222 and contact pad 236b and the solder electrical connection 242 is realized between the electrical connection structure 224a and the contact pad 236a and the electrical connection structure 224b and an additional contact pad 236d.

The electrically conductive layer 248 allowing the electrical connection between the sealing structure 222 and the electrical connection 224b can be provided at least partially around the media channel 234 or even extend entirely around it. In this case, the isolating layer 218 is arranged such that an electrical isolation between the sealing structure 222 and the other electrical connections 224a, 224c and 224d are guaranteed.

A third variant of the invention is shown in FIG. 2f illustrating a MEMs sensor arrangement 250c comprising a transducer element 230c connected to a substrate 232. The only difference between this variant and the transducer element 230b and MEMs sensor arrangement 250b illustrated in FIG. 2e is a different electrical connection between the electrical connection 224a and the electrical contact pad 206a of the sensing element 210a. All other features remain the same and reference is made is to the description above.

In this variant, the electrical connection structure 224a is not directly connected to the electrical contact 206a like in the other embodiments but via an electrically conductive layer 250, which can be realized at the same time as the electric conductive layer 248. Like in the other embodiments, the electrical connection structure 224a is electrically isolated from the sealing structure 222 using the insulating layer 218.

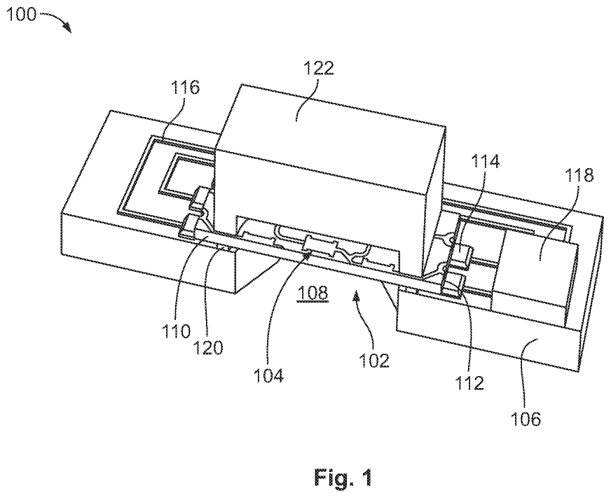

In use, a measurand from a measurement volume enters the MEMs sensor arrangement 250a or 250b via the media channel 234. The membrane 208 of the transducer element 230a deforms under the pressure difference between the measurand and the pressure in the cavity 212. The deformation or stress is sensed by the sensing elements 210a and 210 and electrical signals proportional to the pressure are output via the contact pads 236a and 236b to be treated in the further electrical components, like components 118 shown in FIG. 1.

Using the same solderable material as sealing structure and as electrical connection structure allows realizing the sealing and the electrical connection step of the transducer element with the substrate during the same manufacturing step at the transducer element level. Thus, the assembly process can be shortened and facilitated.

In addition, by providing the electrical connections 224a, 224b below the membrane 208, it is no longer necessary to provide electrical contacts 112 on the side of the like in the prior art as shown in the art. This allows reducing the size of the final transducer element 230a.

In a third variant of the embodiment, not shown, the steps d), e) and f) are performed before step c) of dicing the wafer 200. In this variant, a substrate is provided that comprises a plurality of channels corresponding to the number of transducer elements present on the wafer.

For the following embodiments of the invention and their variants and alternatives, the features in common with the first embodiment and its variants and alternatives will not be described in detail again, but reference is made to their description above and the same reference numbers will be used.

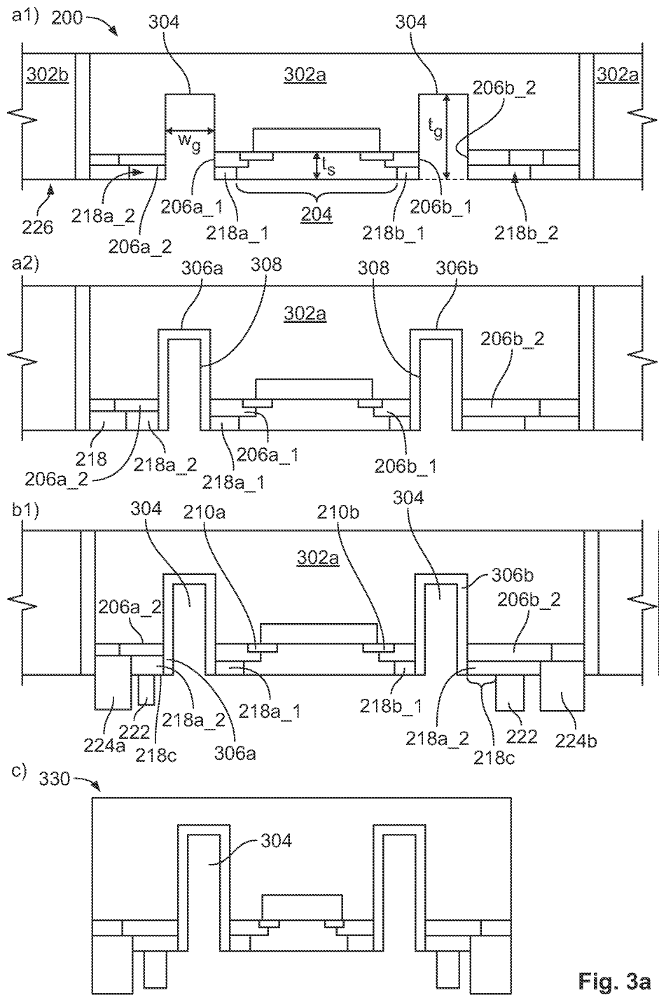

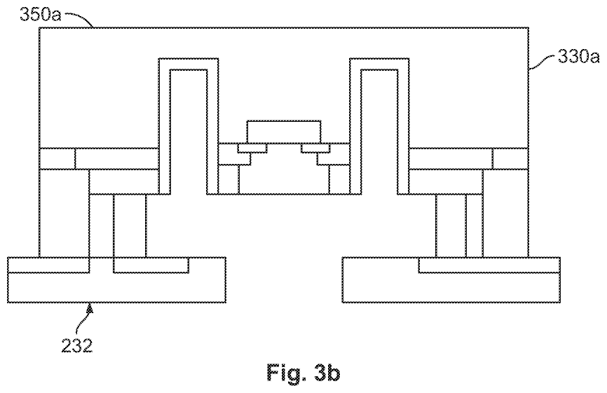

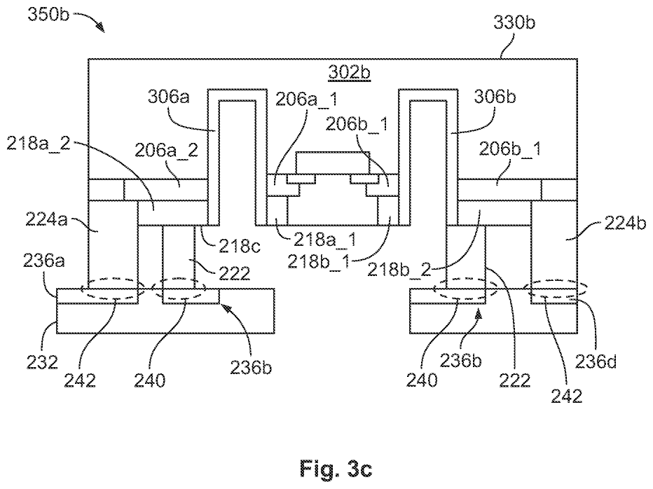

FIG. 3a illustrates a fabrication method of a MEMS transducer element according to a second embodiment of the invention.

In this embodiment, the step a) of realizing a plurality of microelectromechanical transducer elements 302a, 302b, 302c on a wafer 200 comprises the additional patterning process step a1) of realizing a groove 304, in an embodiment, for each transducer element 302a of the plurality of transducer elements realized on the wafer 200. All the other features of the transducer element 302a are the same as the features of the transducer element 202a described in the first embodiment, and reference is made to their description in the first embodiment. Where applicable, the same reference numbers will be used.

Step a1) is realized before step b). The groove 304 is realized around the sensitive region 204 of the transducer element 302a, on the active surface side 226 of the transducer element 302a. The minimum width w_{g} of the groove 304 is set by the limits of the manufacturing process, and can typically range from 10 μm to 400 μm. The minimum depth t_{g} of the groove 304 is deeper than the thickness tₛ of the sensitive region 204. A groove 304 having a depth larger than the thickness tₛ of the sensitive region 204 will provide better stress isolation. The groove 304 separates the electrical contacts 206a, 206b in two parts 206a_1 and 206a_2, 206b_1 and 206b_2, one part on each side of the groove 304. The groove 304 also separates the insulating layer 218 in two parts 218a_1 and 218a_2, 218b_1 and 218b-2, one on each side of the grove 304.

To maintain the electrical connection between the two parts of the electrical contacts 206a_1 and 206a_2, 206b_1 and 206b_2, respective electrically conductive layers 306a and 306b are deposited on the side walls 308 of the groove 304 during step a2) as illustrated in FIG. 3a. The electrically conductive layers 306a, 306b can be metallic layers, e.g. an aluminum or copper layer. The electrically conductive layers 304, 306b are partially deposited within the groove 304 in order to avoid creating an electrical short circuit between the electrical contact pads 206a, 206b, 206c, 206d of the transducer element 302a. The electrically conductive layer 304a, 306b is deposited within the groove 304 so as to provide an electrical connection with the electrical contact pads 206a_1, 206b_1 locally.

For this embodiment, the steps b) and c) are realized in the same way as in the first embodiment and its variants and alternatives. However, as illustrated in step b1) of FIG. 3b, the sealing structure 222 is arranged around the sensitive region 204 on the outer side of the groove 304. Thus, both the sealing structure 222 and the electrical connections 224a, 224b on the electrical contacts 206a_2 and 206b_2 are arranged on the outer side of the groove 304. Indeed, since both the sealing structure 222 and the electrical connections 204 can negatively affect the transducer element 302a, the groove 304 is positioned so as to decouple both areas. The groove 304 is positioned between the sensitive area 204 of the transducer element 302a and both the sealing structure 222 and the electrical connections 224a, 224b, in order for the groove 304 to serve as an outside stress decoupling feature to reduce the influence of external stress onto the sensing elements 210a, 210b. The groove 304 therefore leads to a more reliable transducer element with a reduced sensibility to outside vibrations at the transducer element level.

Furthermore, the sealing structure 222 is deposited on the insulating layer 218a_2, 218b_2 and spaced apart from the electrically conductive layer 306a, 30b, such that a portion 218c of the insulating layer 218a_2, 218b_2 is not covered by the sealing structure 222. Thus, an electrical contact between the sealing structure 222 and the electrically conductive layer 306a, 306b of the groove 304 can be prevented. In this embodiment, the electrically conductive layer 306a, 306b, the sealing structure 222 and the electrical contact 224a, 224b can be made of the same material. In addition, since the groove 304 is integrated into the wafer 200, the transducer element 302a offers a compact design.

Thus, after step c), a transducer element 330a is obtained having all the features of the transducer element 230a of the first embodiment but in addition, the stress decoupling feature in the form of the groove 304.

FIG. 3b illustrates the transducer element 330a soldered to substrate 232 to obtain a MEMs sensor arrangement 350a according to a first variant of the second embodiment. The process steps to obtain the MEMS sensor arrangement 350a correspond to the steps d) to f) of the first variant of embodiment 1.

A second variant is shown in FIG. 3c illustrating a MEMs sensor arrangement 350b comprising a transducer element 330b connected to a substrate 232. The only difference between this variant and the transducer element 330a and MEMs sensor arrangement 350a, illustrated in FIG. 3b is a different electrical connection between the sealing structure 222 and the electrical connection 224b and between the electrical connection 224a and the electrical contact 206a_2. All other features remain the same and reference made is to the description above.

Instead of realizing the electrical connection between the sealing structure 222 and the electrical connection 224b on the substrate 232 side using the contact pad 236c as shown in FIG. 2d, the electrical connection is realized on the transducer element 302b side using the electrically conductive layer 306b present within the groove 304.

In this variant, the sealing structure 222 is deposited on top of the insulating layer 218b_2 but in contact with the electrically conductive layer 306b, and thus is also electrically connected with the electrical contact 206b_2 and with the electrical connection 224b. The insulating layer 218b_2 remains, however, present between the electrical contact 206b_2 and the sealing structure 222. According to a variant, a layer 218 could be present like in FIG. 2f.

The solder connection 240 with the substrate 232 is then realized between the sealing structure 222 and contact pad 236b and the solder electrical connection 242 between the electrical connection structure 224a and the contact pad 236a and the electrical connection structure 224b and an additional contact pad 236d. The solder connection 240 extends around the media channel 234.

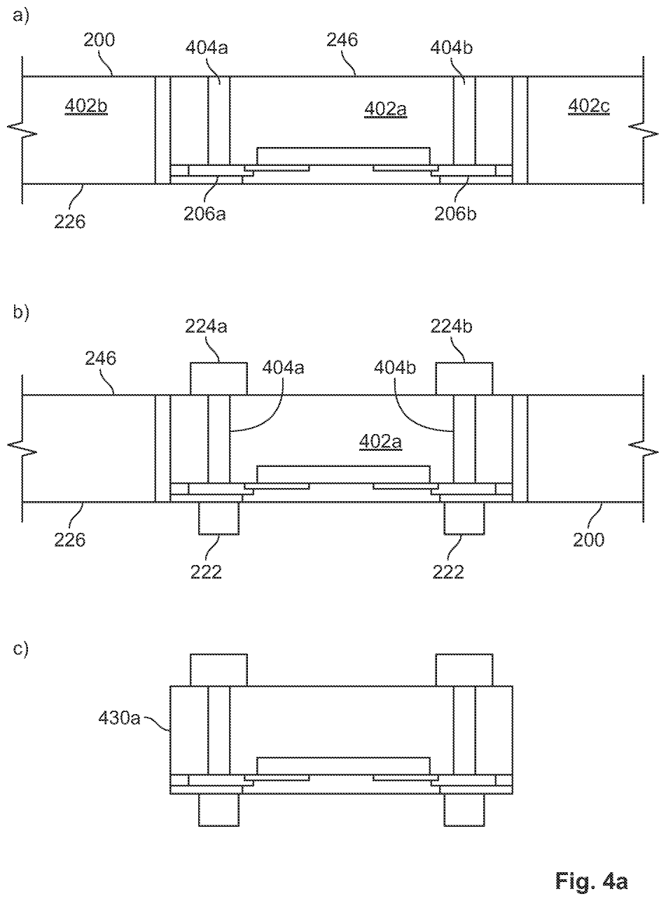

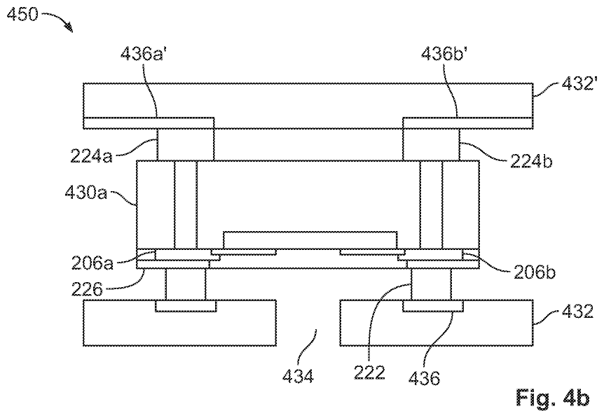

FIG. 4a illustrates a fabrication method of a MEMS transducer element according to a third embodiment of the invention.

In this embodiment, the step a) of realizing a plurality of microelectromechanical transducer elements on a wafer 200 comprises additional process steps of providing vias 404a, 404b, e.g. so called through silicon vias (TSV), through the wafer 200 of the transducer element 402a, 402b, 402c.

First corresponding through holes are realized through the wafer 200 which are then filled with an electrically conductive material, in particular metal. All the other features of the transducer element 402a are the same as the features of the transducer element 202a described in the first embodiment, and reference is made to their description in the first embodiment. In addition, the same reference numbers are used where appropriate.

The vias 404a, 404b are positioned such as to allow an electrical connection with the electrical contacts 206a, 206b on the opposite surface side 246, opposite to the active surface side 226.

During step b) of this embodiment, the electrical connections 224a, 224b and the sealing structure 222 are then realized on opposite surface sides of the wafer 200, i.e. of the transducer element 402a.

As shown in step b) of FIG. 4a, the sealing structure 222 is provided on the surface side 226 of the transducer element 202a where the sensitive region 204, i.e. the membrane 208, is provided.

The electrical connection structures 224a, 224b are provided on the opposite side 246 of the active surface side 226 of the transducer element 202a, in direct contact with the vias 404a, 404b respectively.

After dicing, as shown in step c), an individual transducer element 430a is obtained.

This transducer element 430a can then be mounted to two different substrates 432 and 432′ as illustrated in FIG. 4b, to realize a MEMs sensor arrangement 450 according to a variant of the third embodiment. The transducer element 430a is mounted on its active surface side 226 to a substrate 432 using the sealing structure 222. Furthermore, the transducer element 430 is mount to the substrate 432′ using the electrical connections 224a, 224b on its other surface side 246. The transducer element 430a is thus sandwiched between two substrates 432, 432′.

The substrate 432 comprises a media channel 434, like substrate 232 and electrical conductive pad 436 so that the sealing structure 222 can be attached using soldering like in the first and second embodiment.

The second substrate 432′ comprises electrical conductive pads 436a, 436b to realize the electrical connections with the electrical contacts 206a and 206b.

By arranging, the sealing on the one side and the electrical connections on the other side a more compact design can be realized and, in addition, the electrical components can be arranged further away from the media channel 434.

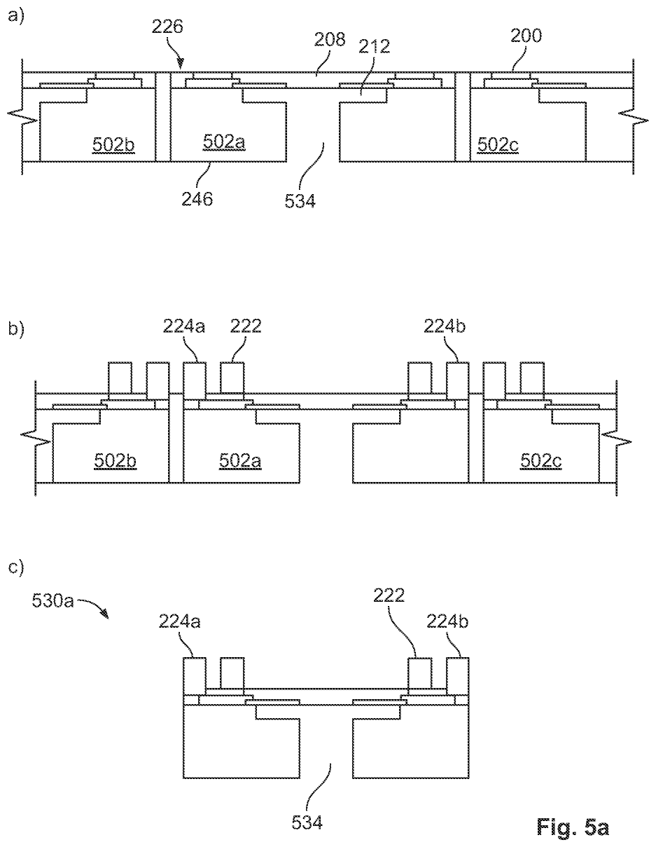

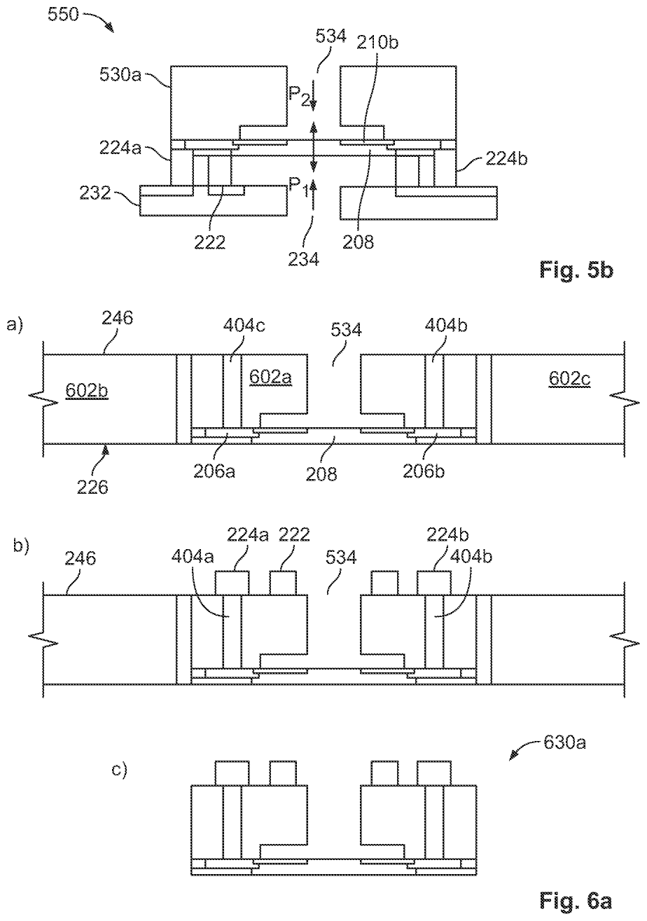

FIG. 5a illustrates a schematic view of a fabrication method of microelectromechanical (MEMs) transducer elements 502a, 502b, 502c fabricated according to a fourth embodiment of the invention.

In this embodiment, an additional process step is realized during step a) to provide a media channel 534 for each transducer element 502a, 502b, 502c in the wafer 200. The media channel 534 is realized such that it extends from the opposite surface side 246 with respect to the active surface side 226 up until the cavity 212 and the membrane 208. All the other features of the transducer element 502a are the same as the features of the transducer element 202a described in the first embodiment, and reference is made to their description in the first embodiment. In addition, the same reference numbers are used where appropriate.

Otherwise, the transducer element 502a is realized using the same process steps as described above concerning the first embodiment. Thus, during step b) of this embodiment, the electrical connections 224a, 224b and the sealing structure 222 are realized on the transducer elements 502a, 502b, 502c and after dicing of step c) an individual transducer element 530a with a media channel 534, the electrical connections 224a, 224b and the sealing structure 222 is obtained.

FIG. 5b illustrates a schematic view of a microelectromechanical sensor arrangement 550 according to a variant of the fourth embodiment of the invention using the transducer element 530a with the media channel 534 and the substrate 232 with the media channel 234 to realize a differential pressure sensor. Again, the transducer element 530a is attached to the substrate 232 by heating the electrical connections 224a and 224b and the sealing structure 222 above their fusion point.

In this configuration, a first media channel, media channel 234 is provided through which a first media under pressure P1 can impinge on the membrane 208 and a second media channel, media channel 534, is provided through which a second media under pressure P2 can impinge on the membrane 208 from the other side. The sensing elements 210a, 210b detect the displacement or stress of the membrane 208 induced by the pressure difference P1-P2 between media acting on the two sides of the membrane 208, indicated by the double arrow. Thus, a differential pressure measurement can be realized.

Again, according to the invention, the sensor 550 can be integrated using the sealing structure 222 and the electrical connections 224a, 224b already provided at the OEM, thus at wafer level.

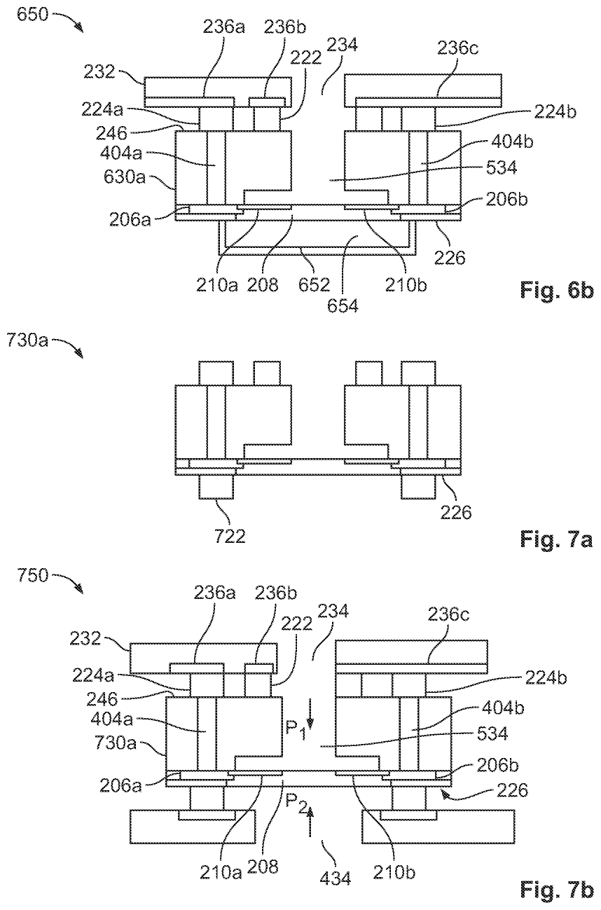

FIG. 6a illustrates a schematic view of a fabrication method of microelectromechanical transducer element fabricated according to a fifth embodiment of the invention. This embodiment combines the features of the third and fourth embodiment.

In this embodiment, step a) consists in providing a transducer elements 602a, 602b, 602c comprising vias, 404a, 404b connecting the opposite surface side 246 with the electrical contacts 206a and 206 on the membrane 208 on the active surface side 226, like in the third embodiment as shown in FIG. 4a, and a media channel 534, as shown in the FIG. 5a in the fourth embodiment. The description of the method will therefore not be repeated again but it is referred to the detailed description of the third and fourth embodiment. Furthermore, all the other features of the transducer element 602a are the same as the features of the transducer element 202a described in the first embodiment, and reference is made to their description in the first embodiment. In addition, the same reference numbers are used where appropriate.

The method according to the fifth embodiment then comprises a step b) of providing a sealing structure 222 and electrical connections 224a, 224b on the opposite surface side 246. The electrical connection structures 224a, 224b are provided in direct contact with the vias 404a, 404b respectively like in the third embodiment. The sealing structure 222 is realized to surround the media channel 534.

After dicing, like illustrated by step c) in FIG. 6a, an isolated transducer element 630a is obtained.

FIG. 6b illustrates a schematic view of a microelectromechanical sensor arrangement 650 according to a variant of the fifth embodiment. In this embodiment, the transducer element 630a is attached with its opposite surface side 246 to a substrate 232 with media channel 234 using process steps d) to f) as illustrated in FIG. 2d. The attachment is realized by heating the solder material above its fusion point and cooling down like in the other embodiments.

The soldering step takes place as in the other embodiments between the sealing structure 222, the electrical connection structures 224a, 224b and the electrical contact pads 236a, 236b, 236c of the substrate 232 to form a seal and an electrical connection.

In this embodiment, the seal realized by the sealing structure 222 and the substrate 232 protects the electrical connection structures 224a, 224b from any media in the media channel 234.

The electrical connection structures 224a, 224b provide an electrical connection between the sensing elements 210a, 210b of the membrane 208, in particular the piezoresistive gauge 210a, 210b of the membrane 208, via the electrical contacts 206a, 206b and the vias 404a, 404b with the substrate 232 and other electrical component present in a sensor arrangement.

A cap 652, shown in FIG. 6b, is provided to realize a reference volume 654 on the active surface side 226 of the membrane 208 of the transducer element 630a. In this configuration, a pressure sensor is realized in which the media enters via the media channel 234 and the media channel 534 to deform the membrane 208 against the pressure in the reference volume 654.

FIG. 7a illustrates a schematic view of a transducer element 730a fabricated according to a sixth embodiment of the invention. The fabrication process to obtain the transducer element 730a according to the sixth embodiment is similar to the one of the fifth embodiment, except that in step b) a second sealing structure 722 is provided on the active surface side 226. Besides that, all features of the transducer element 730a are the same as for the transducer element 630 illustrated in FIG. 6a, reference is therefore made to its description above. The second sealing structure 722 is made of the same material as the sealing structure 222 and is deposited in the same way either before or after the process step of realizing structure 222.

FIG. 7b illustrates a schematic view of a microelectromechanical sensor arrangement 750 according to a variant of the sixth embodiment. In this embodiment, like fourth embodiment illustrate in FIG. 5b, a differential pressure sensor is realized. To do so a substrate 232 is attached to the opposite surface side 246 of the transducer element 730a. Attachment is realized by heating the solder material above its fusion point and cooling down like in the other embodiments.

The soldering step takes place as in the other embodiments between the sealing structure 222, the electrical connection structures 224a, 224b and the electrical contact pads 236a, 236b, 236c of the substrate 232 to form a seal and an electrical connection.

In this embodiment, the seal realized by the sealing structure 222 and the substrate 232, protects the electrical connection structures 224a, 224b from any media in the media channel 234 and 534.

The electrical connection structures 224a, 224b provide an electrical connection between the piezoresistive gauge 210a, 210b of the membrane 208 via the electrical contacts 206a, 206b and the vias 404a, 404b with the substrate 232 and other electrical component present in a sensor arrangement.

A second substrate 432, like already used in the third embodiment as illustrated in FIG. 4b is attached on the active surface side 226, as shown in FIG. 7b.

The soldering step takes place between the second sealing structure 722 and the conductive pad 436. Thus, a second seal is realized by the sealing structure 722 and the substrate 432 to protect the electrical connection structures 224a, 224b from any media in the second media channel 434.

In this configuration, a first media channel, media channel 234 and 534 is provided through which a first media under pressure P1 can impinge on the membrane 208 and a second media channel, media channel 434, is provided through which a second media under pressure P2 can impinge on the membrane 208 from the other side. The sensing elements 210a, 210b detect the displacement of the membrane 208 induced by the pressure difference P1-P2 between the media acting on the two sides of the membrane 208, indicated by the double arrow. Thus, a differential pressure measurement can be realized like in the variant of the fourth embodiment illustrated in FIG. 5b.

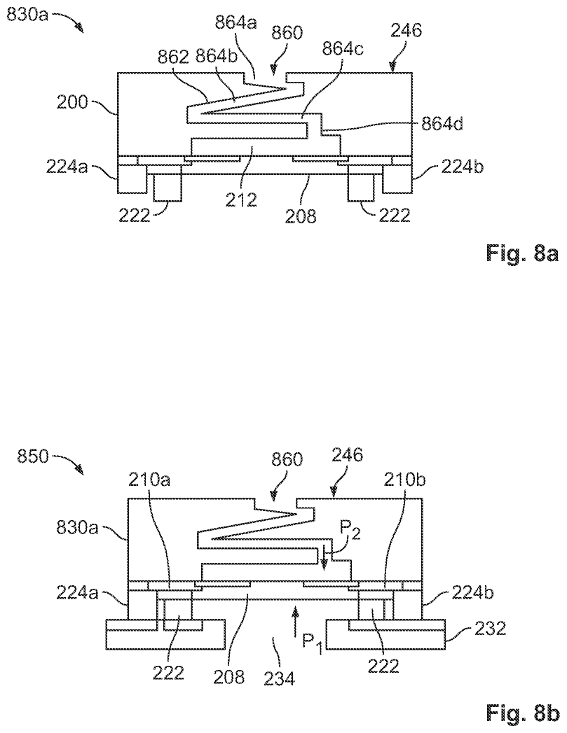

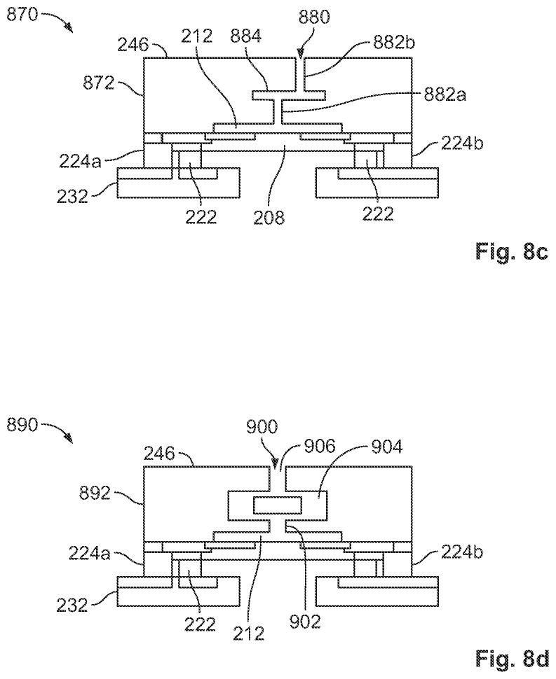

FIG. 8a illustrates a schematic view of a fabrication method of microelectromechanical (MEMs) transducer element 830a fabricated according to a seventh embodiment of the invention. This embodiment is similar to the fourth embodiment illustrated in FIGS. 5a and 5b. The difference between the two embodiments is the use of a snubber structure 860 as media channel instead of the media channel 534 illustrated in FIGS. 5a and 5b. In pressure sensors, snubber structures are used to mitigate transient events of high pressure, e.g. pressure spikes, which can cause damage of the membrane when the pressure peak leads to a membrane deformation beyond its predetermined yield point, as already known from EP3748325A1, the description of which is incorporated herewith by reference.

Besides the use of a snubber structure 860, all other features are the same as in the fourth embodiment and the transducer element 830a can be realized using the same process steps and is not described in detail again. Instead, reference is made to the detailed description of the fourth embodiment.

Instead of realizing the media channel 534, microelectromechanical production steps as known in the art, for example a succession of dry or wet etching and wafer bonding steps or other alternatives like 3D glass laser structuring, are realized to provide the wafer 200 with an integrated snubber structure 860.

The integrated snubber structure 860 in this embodiment comprises a through channel 862 reaching from the opposite surface side 246 of the transducer element 830a to the cavity 212. The channel 862 comprises two or more portions, in this example four portions 864a, 864b, 864c, 864d, with changing directions to mitigate transient pressure events. Providing integrating snubber structures 860 inside the wafer 200 allows reducing the size of the transducer element 830a and improves the integration into a complete pressure sensor.

According to the invention, the transducer element 830a of the sixth embodiment furthermore comprises a sealing structure 222 and electrical connections 224a, 224b on the active surface side 226.

FIG. 8b illustrates a variant of the sixth embodiment. The transducer element 830a is attached to substrate 232, similar to the variant of the fourth embodiment illustrated in FIG. 5b, to form a microelectromechanical sensor arrangement 850 according to a variant of the seventh embodiment of the invention using the transducer element 830a with the snubber structure 860 and the substrate 232 with the media channel 234 to realize a differential pressure sensor. Also in this variant, the transducer element 830a is attached to the substrate 232 by heating the electrical connections 224a and 224b and the sealing structure 222 above their fusion point.

In this configuration, a first media channel, media channel 234 is provided through which a first media under pressure P1 can impinge on the membrane 208 and a second media channel, snubber structure 860, is provided through which a second media under pressure P2 can impinge on the membrane 208 from the other side. The sensing elements 210a, 210b detect the displacement of the membrane 208 induced by the pressure difference P1-P2 between media acting on the two sides of the membrane 208, indicated by the double arrow. Thus, a differential pressure measurement can be realized.

According to the invention, the sensor 850 can be integrated at the site of an OEM, thus already at wafer level, by using the sealing structure 222 and the electrical connections 224a, 224b.

According to further variants, the transducer element 830a and the Mems sensor arrangement 850 could be combined with features of the other embodiment. E.g. vias 404a, 404b could be used to provide the electrical contact on the opposite side surface 246. Furthermore, instead of realizing a differential pressure sensor, a pressure sensor having only one media channel, the snubber structure 860, and using a cap 652 as illustrated in the variant of the fifth embodiment of FIG. 6b, could be realized.

A second variant of a Mems sensor arrangement 870 according to the seventh embodiment comprises a transducer element 872 with an integrated snubber structure 880 attached to a substrate 232 as illustrated in FIG. 8c. Also in this variant, the transducer element 872 is attached to the substrate 232 by heating the electrical connections 224a and 224b and the sealing structure 222 above their fusion point. The same process steps can realize this sensor arrangement 870 as the one illustrated in FIG. 8b.

The integrated snubber structure 880 comprises a first channel 882a perpendicular to the cavity 212 behind the membrane 208, followed by a second cavity 884 parallel to the first cavity 212 and a second channel 882b again perpendicular which extends through to the opposite surface side 246.

The sensor arrangement 870 as illustrated in FIG. 8c is a differential pressure sensor, as the one illustrated in FIG. 8b but could also be realized as a pressure sensor having only one medial channel and a cap like illustrated in the variant of the fifth embodiment of FIG. 6b. Furthermore, also in this sensor arrangement 870 vias could be used to move the electrical connections to the opposite surface side 246.

A third variant of a Mems sensor arrangement 890 according to the seventh embodiment comprises a transducer element 892 with an integrated snubber structure 900 attached to a substrate 232 as illustrated in FIG. 8d. Also in this variant, the transducer element 892 is attached to the substrate 232 by heating the electrical connections 224a and 224b and the sealing structure 222 above their fusion point. The same process steps as the one illustrated in FIG. 8b or 8c can realize this sensor arrangement 890.

The integrated snubber structure 900 in FIG. 8d comprises a first channel 902 in connection with the cavity 212 and an internal cavity 904. The internal cavity 904 in turn is connected to a second channel 906 that extends through to the opposite surface side 246. A pressure mitigation element 908 is furthermore provided inside the internal cavity 904. This pressure mitigation member 908 is a movable element, like a piston, that is configured and formed from a material that enables it to move within the separate cavity to block the first channel 902 under a pressure spike.

The sensor arrangement 890 as illustrated in FIG. 8d is a differential pressure sensor, like the one illustrated in FIG. 8b or 8c, but could also be realized as a pressure sensor having only one medial channel and a cap like illustrated in the variant of the fifth embodiment of FIG. 6b. Furthermore, also in this sensor arrangement 890 vias could be used to move the electrical connections to the opposite surface side 246.

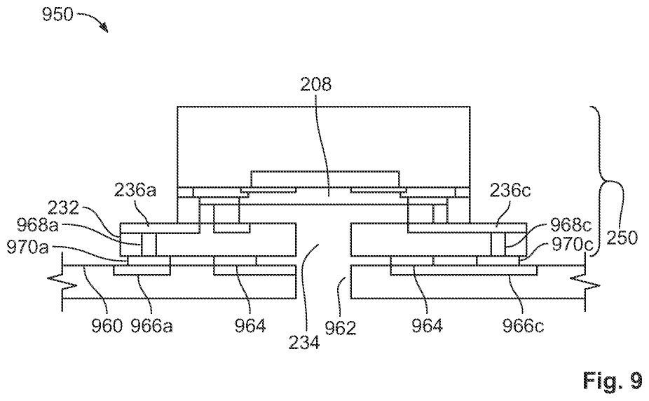

FIG. 9 illustrates a schematic view of a microelectromechanical sensor system 950 according to an eight embodiment of the invention.

In this embodiment, a Mems sensor arrangement 250 is mount on a circuit carrier 960. The circuit carrier 960 can be part of a printed circuit board or a flexible board, having further electronic components mounted thereon. According to variants, any one of the Mems sensor arrangements 350a, 350b 450, 550, 650, 750, 870, 850 or 890 according to one of the embodiments two to seven and their variants could be mount instead.

In FIG. 9, the circuit carrier 960 comprises a media channel 962 aligned with the media channel 234 of the sensor arrangement 250a so that a measurand can impinge on the membrane 208.

A solder seal 964 seals the media channel 962 at the interface between the circuit carrier 960 and the substrate 232 of the MEMs sensor arrangement 250a. The circuit carrier 960 further comprises electrical contact pads 966a and 966c electrically connected with the electrical contact pads 236a and 236c of the substrate 232, e.g. using vias 968a, 968c in the substrate 232 and solder connections 970a and 970c.

Also in this embodiment, the solder seal 964 and the solder connections 970a and 970c can be of the same material, so that the sealing and electrical connections can be realized in one step.

A number of embodiments of the invention have been described. Nevertheless, it is understood that various modifications and enhancements may be made without departing the following claims.

What is claimed is:

1. A method of fabricating a plurality of individual microelectromechanical transducer elements, comprising the steps of:
forming a plurality of microelectromechanical transducer elements on a wafer, each microelectromechanical transducer element has a sensitive region with a membrane and a sensing element monitoring at least one measurand and generating an electrical signal correlated with the at least one measurand, and an electrical contact outputting the electrical signal;
providing, for each microelectromechanical transducer element, a sealing structure around a sensitive region and an electrical connection connected to the electrical contact, the sealing structure and the electrical connection are made out of a reflow solder material; and
dicing the wafer to form individual microelectromechanical transducer elements.

2. The method of claim 1, wherein, during the providing step, the sealing structure and the electrical connection are formed during a same process step.

3. The method of claim 1, wherein the providing step includes providing the sealing structure and the electrical connection over a same surface side of the wafer.

4. The method of claim 1, wherein the electrical connection and the sealing structure are disposed over opposite sides of the wafer.

5. The method of claim 1, further comprising providing at least one via extending through the wafer per microelectromechanical transducer element.

6. The method of claim 1, further comprising, before the dicing step:
providing a substrate including a plurality of channels extending through the substrate;
aligning each channel with the sensitive region of one of the microelectromechanical transducer elements; and
attaching the substrate to the wafer using the sealing structures and the electrical connections to seal an interface between the sensitive regions and the substrate from a remaining region of the microelectromechanical transducer elements and to electrically connect the electrical contacts of the microelectromechanical transducer elements with a plurality of mating electrical contacts of the substrate.

7. The method of claim 6, wherein the attaching step includes soldering the sealing structures and the electrical connections.

8. The method of claim 1, further comprising providing an integrated snubber structure inside the wafer in the sensitive region.

9. The method of claim 1, further comprising providing a groove in the wafer around the sensitive region.

10. The method of claim 9, wherein the groove, after the providing step, is positioned between the sensitive region and both the sealing structure and the electrical connection.

11. The method of claim 1, further comprising, prior to the dicing step, providing a channel in the wafer, the channel at least partially aligned with the sensitive region.

12. A microelectromechanical transducer element, comprising:
a sensitive region with a membrane and a sensing element on a transducer substrate monitoring at least one measurand and generating an electrical signal correlated with the at least one measurand, and an electrical contact outputting the electrical signal;
a sealing structure; and
an electrical connection made out of a same material as the sealing structure, the sealing structure and the electrical connection are provided on a same surface of the transducer substrate.

13. The microelectromechanical transducer element of claim 12, wherein the sealing structure and the electrical connection are made of a solder material.

14. The microelectromechanical transducer element of claim 13, wherein the sealing structure and the electrical connection are made of a reflow solder material.

15. The microelectromechanical transducer element of claim 12, further comprising a via provided in the transducer substrate and connecting the electrical contact with the electrical connection.

16. The microelectromechanical transducer element of claim 12, further comprising a channel within the transducer substrate.

17. The microelectromechanical transducer element of claim 16, wherein the channel is in fluidic connection with the membrane.

18. The microelectromechanical transducer element of claim 17, wherein the channel is a snubber structure.

19. The microelectromechanical transducer element of claim 12, wherein the transducer substrate has a groove positioned between the sensitive region and both the sealing structure and the electrical connection.

20. A microelectromechanical sensor arrangement, comprising:
a microelectromechanical transducer element having a sensitive region with a membrane and a sensing element on a transducer substrate monitoring at least one measurand and generating an electrical signal correlated with the at least one measurand, and an electrical contact outputting the electrical signal, a sealing structure, and an electrical connection made out of a same material as the sealing structure; and
a substrate having a channel, the microelectromechanical transducer element is mounted on the substrate such that the media channel is in fluidic connection with the membrane of the sensitive region, the sealing structure surrounds the channel and is sandwiched between the microelectromechanical transducer element and the substrate and the electrical connection, the sealing structure electrically connects the microelectromechanical transducer element and the substrate.
